(19) United States
(12) Patent Application Publication
(10) Pub. No.: US 2026/0182232 A1
(43) Pub. Date: Jun. 25, 2026

(54) DISPLAY DEVICE

(71) Applicant: Japan Display Inc., Tokyo (JP)

(72) Inventor: Junko NAGASAWA, Tokyo (JP)

(73) Assignee: Japan Display Inc., Tokyo (JP)

(21) Appl. No.: 19/422,502

(22) Filed: Dec. 17, 2025

(30) Foreign Application Priority Data
Dec. 24, 2024 (JP) 2024-227253

(51) Int. Cl. H10K 59/80; H10K 59/38; H10K 102/00

(52) U.S. Cl. CPC H10K 59/8792; H10K 59/38; H10K 59/871; H10K 59/879; H10K 2102/351

(57) ABSTRACT

According to one embodiment, a display device includes a first display element, a second display element, a rib surrounding each of the first display element and the second display element, an organic insulating layer provided above the first display element and the second display element, and a first light-shielding layer provided between the first display element and the second display element. The first light-shielding layer has a first opening overlapping part of the first display element and a second opening overlapping part of the second display element. The first light-shielding layer includes a first layer located on the organic insulating layer and a second layer located on the first layer and formed of a material different from that of the first layer.

### CROSS-REFERENCE TO RELATED APPLICATIONS

This application is based upon and claims the benefit of priority from Japanese Patent Application No. 2024-227253, filed Dec. 24, 2024, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. This type of display devices demands a technique for improving display quality.

In another type of display device, namely an active-matrix liquid crystal display, a technique is known in which red, green, and blue color filters are stacked at positions facing a drive circuit portion to constitute a light-shielding film.

### BRIEF DESCRIPTION OF THE DRAWINGS

FIG. 1 is a view showing a configuration example of a display device DSP.

FIG. 2 is a diagram showing an example of the layout of subpixels SP1, SP2, and SP3 which constitute one pixel PX.

FIG. 3 is a view for describing a configuration example of the pixel PX.

FIG. 4 is a plan view for describing a configuration example 1.

FIG. 5 is a schematic cross-sectional view of the display device DSP along the A-B line of FIG. 4.

FIG. 6 is a schematic cross-sectional view of a modified example 1.

FIG. 7 is a schematic cross-sectional view of a modified example 2.

FIG. 8 is a plan view for describing a configuration example 2.

FIG. 9 is a schematic cross-sectional view of the display device DSP along the C-D line of FIG. 8.

FIG. 10 is a schematic cross-sectional view of a modified example 3.

FIG. 11 is a schematic cross-sectional view of a modified example 4.

FIG. 12 is a plan view for describing a configuration example 3.

FIG. 13 is a schematic cross-sectional view of the display device DSP along E-F line of FIG. 12.

FIG. 14 is a plan view for describing a configuration example 4.

FIG. 15 is a schematic cross-sectional view of the display device DSP along the G-H line of FIG. 14.

FIG. 16 is a schematic cross-sectional view of a configuration example 5.

FIG. 17 is a plan view for describing a variation 1.

FIG. 18 is a plan view for describing a variation 2.

FIG. 19 is a plan view for describing a configuration example 6.

FIG. 20 is a schematic cross-sectional view of the display device DSP along the I-J line of FIG. 19.

FIG. 21 is a schematic cross-sectional view of a configuration example 7.

FIG. 22 is a schematic cross-sectional view for describing a configuration example 8.

FIG. 23 is a schematic cross-sectional view for describing a configuration example 9.

FIG. 24 is a schematic cross-sectional view for describing a configuration example 10.

FIG. 25 is a plan view for describing a variation 3.

FIG. 26 is a plan view for describing a variation 4.

### DETAILED DESCRIPTION

An object of embodiments is to provide a display device capable of improving display quality.

In general, according to one embodiment, a display device includes a substrate, a first display element and a second display element provided above the substrate, a rib formed in a lattice shape surrounding each of the first display element and the second display element, a transparent organic insulating layer provided above the first display element and the second display element, and a first light-shielding layer provided between the first display element and the second display element on the organic insulating layer. The first light-shielding layer has a first opening overlapping part of the first display element and a second opening overlapping part of the second display element. The first light-shielding layer includes a first layer located on the organic insulating layer and a second layer located on the first layer and formed of a material different from that of the first layer

Embodiments can provide a display device capable of improving the display quality.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as an upward direction or a direction to an upper side.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

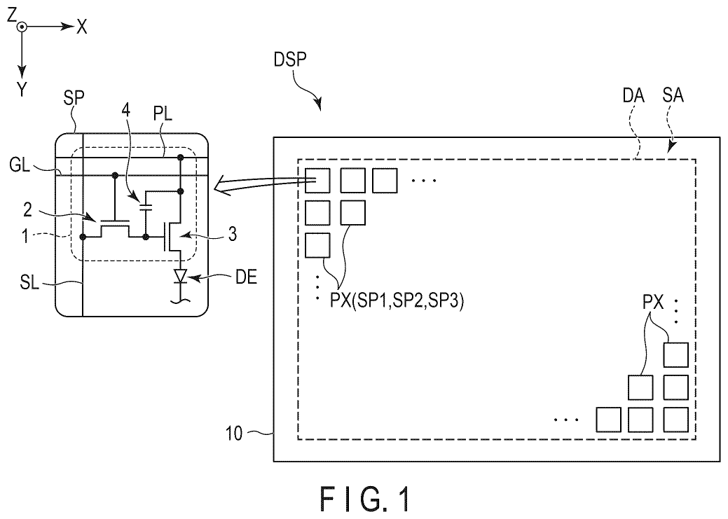

FIG. 1 is a view showing a configuration example of a display device DSP.

The display device DSP has a display area DA for displaying images and a surrounding area SA around the display area DA on an insulating substrate 10. The substrate 10 may be either a glass substrate or a resinous substrate having flexibility.

The display area DA comprises a plurality of pixels PX arranged in a matrix in the first direction X and the second direction Y. Each pixel PX includes a plurality of subpixels SP that display different colors. For example, each pixel PX includes a subpixel SP1, which displays the first color, a subpixel SP2, which displays the second color, and a subpixel SP3, which displays the third color. The first color, the second color, and the third color are mutually different colors. Each pixel PX may include a subpixel SP, which displays another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode and a drain electrode of the pixel switch 2 is connected to a signal line SL. The other is connected to a gate electrode of the drive transistor 3 and the capacitor 4. In the drive transistor 3, one of a source electrode and a drain electrode is connected to a power line PL and the capacitor 4. The other is connected to the display element DE. In the illustrated example, the scanning line GL and the power line PL extend in the first direction X and the signal line SL extends in the second direction Y.

The configuration of the pixel circuit 1 is not limited to the illustrated example. For example, the pixel circuit 1 may comprise more thin-film transistors and capacitors.

For example, the display element DE is an organic light emitting diode (OLED) as a light emitting element and thus may be called an organic EL element.

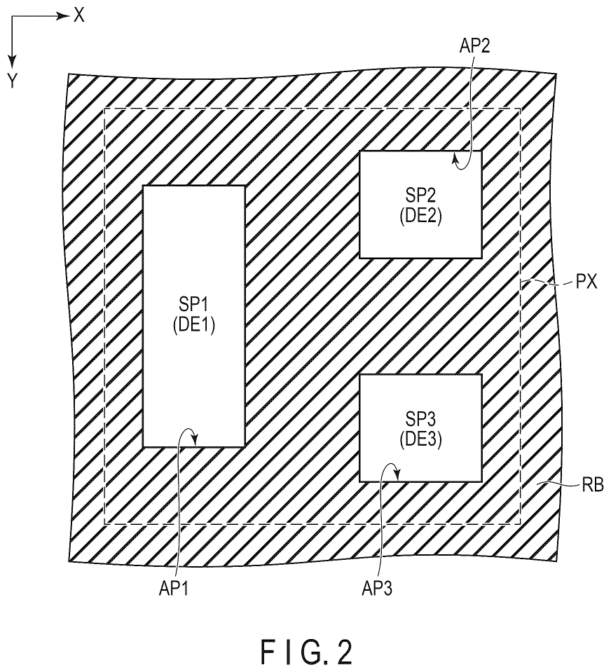

FIG. 2 is a diagram showing an example of the layout of the subpixels SP1, SP2, and SP3 which constitute one pixel PX.

In the illustrated example, in the pixel PX, the subpixel SP1 extends in the second direction Y, and the subpixels SP2 and SP3 are arranged in the second direction Y. Further, the subpixels SP1 and SP2 are arranged in the first direction X, and the subpixels SP1 and SP3 are arranged in the first direction X.

The subpixels SP1, SP2, and SP3 comprise respective display elements DE1, DE2, and DE3 as the display elements DE. Each of the display elements DE1, DE2, and DE3 is surrounded by a rib RB. That is, the rib RB is formed in a lattice shape having respective apertures AP1, AP2, and AP3 in the subpixels SP1, SP2, and SP3.

In the illustrated example, the planar size of the aperture AP1 is greater than those of the apertures AP2 and AP3. The shape and the magnitude relationship of the planar sizes of the apertures AP1, AP2, and AP3 and the layout of the subpixels SP1, SP2, and SP3 are not limited to the illustrated example.

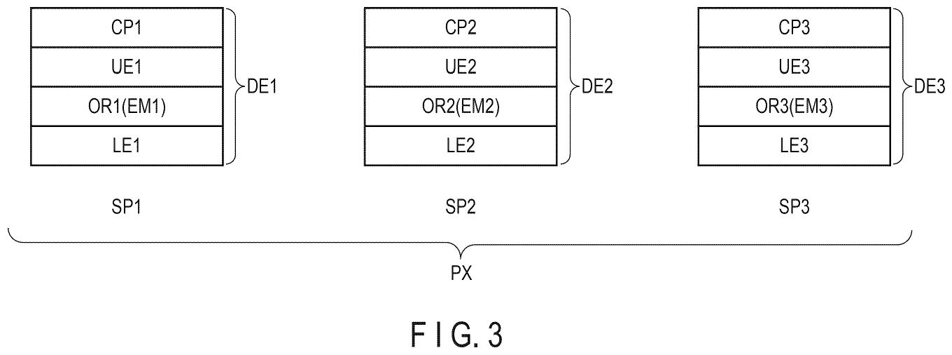

FIG. 3 is a view for describing a configuration example of the pixel PX.

In the subpixel SP1, the display element DE1 comprises a lower electrode LE1, an organic layer OR1, an upper electrode UE1, and a cap layer CP1. The organic layer OR1 including a light emitting layer EM1 is provided between the lower electrode LE1 and the upper electrode UE1. The cap layer CP1 is provided on the upper electrode UE1.

In the subpixel SP2, the display element DE2 comprises a lower electrode LE2, an organic layer OR2, an upper electrode UE2, and a cap layer CP2. The organic layer OR2 including a light emitting layer EM2 is provided between the lower electrode LE2 and the upper electrode UE2. The cap layer CP2 is provided on the upper electrode UE2.

In the subpixel SP3, the display element DE3 comprises a lower electrode LE3, an organic layer OR3, an upper electrode UE3, and a cap layer CP3. The organic layer OR3 including a light emitting layer EM3 is provided between the lower electrode LE3 and the upper electrode UE3. The cap layer CP3 is provided on the upper electrode UE3.

Each of the lower electrodes LE1, LE2, and LE3 corresponds to the anode electrically connected to the drive transistor 3 of the pixel circuit 1 shown in FIG. 1. For example, each of the lower electrodes LE1, LE2, and LE3 is a multilayer body including a transparent layer formed of an oxide conductive material such as an indium tin oxide (ITO) and a reflective layer formed of a metal material such as silver.

The upper electrodes UE1, UE2, and UE3 correspond to cathodes and may be formed individually or formed as one common electrode across the subpixels SP1, SP2, and SP3. The upper electrodes UE1, UE2, and UE3 are formed of, for example, a metal material such as an alloy of magnesium and silver (MgAg).

The light emitting layers EM1, EM2, and EM3 are formed of mutually different materials. For example, the light emitting layer EM1 is formed of a material that emits light in a blue wavelength range. The light emitting layer EM2 is formed of a material that emits light in a green wavelength range. The light emitting layer EM3 is formed of a material that emits light in a red wavelength range. That is, the display element DE1 is configured to display blue as the first color, the display element DE2 is configured to display green as the second color, and the display element DE3 is configured to display red as the third color.

The light emitting layer EM1 may be formed of a material that emits light in a green wavelength range. The light emitting layer EM2 may be formed of a material that emits light in a blue wavelength range. That is, the display element DE1 may be configured to display green as the first color, and the display element DE2 may be configured to display blue as the second color.

In addition to the light emitting layer, each of the organic layers OR1, OR2, and OR3 has a plurality of functional layers such as a hole injection layer, a hole transport layer, an electron blocking layer, a hole blocking layer, an electron transport layer, and an electron injection layer.

The cap layers CP1, CP2 and CP3 function as optical adjustment layers, which improve the extraction efficiency of light emitted from the respective organic layers OR1, OR2, and OR3. Each of the cap layers CP1, CP2, and CP3 is a multilayer body consisting of a plurality of thin films. All of the thin films are transparent and have mutually different refractive indices. The cap layers CP1, CP2, and CP3 may be omitted.

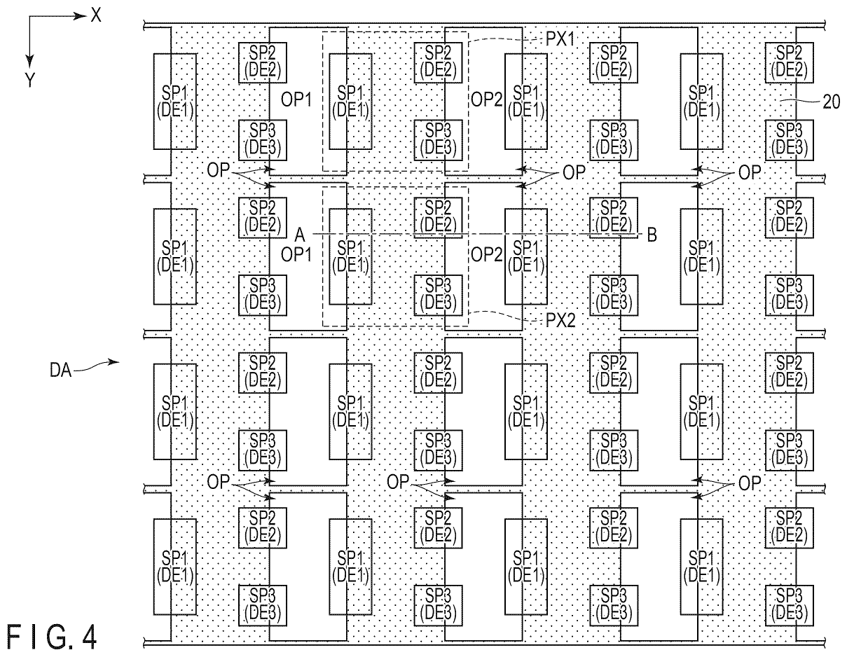

FIG. 4 is a plan view for describing the configuration example 1.

In the display area DA, a column in which the plurality of subpixels SP1 (or the plurality of display elements DE1) are arranged in the second direction Y, and a column in which the subpixel SP2 and the subpixel SP3 (or the display element DE2 and the display element DE3) are alternately arranged in the second direction Y are formed. In the first direction X, the subpixel SP1 and the subpixel SP2 (or the display element DE1 and the display element DE2) are alternately arranged, and the subpixel SP1 and the subpixel SP3 (or the display element DE1 and the display element DE3) are alternately arranged.

A light-shielding layer 20 is provided to overlap the display area DA in plan view. The light-shielding layer 20 has a plurality of openings OP arranged in a matrix in the first direction X and the second direction Y. In the illustrated example, each of the openings OP extends in the second direction Y and has a rectangular shape.

The following mainly describes on two pixels PX1 and PX2 arranged in the second direction Y, of the plurality of pixels arranged in the display area DA.

In the pixel PX1, the light-shielding layer 20 is provided between the display element DE1 and the display element DE2 and between the display element DE1 and the display element DE3, and overlaps a part (the right part) of the display element DE1, a part (the left part) of the display element DE2, and a part (the left part) of the display element DE3.

The plurality of openings OP include an opening OP1 and an opening OP2 arranged in the first direction X. The opening OP1 is located on the left side of the pixel PX1 and overlaps the other part (left part) of the display element DE1. The opening OP2 is located on the right side of the pixel PX1 and overlaps the other part (the right part) of the display element DE2 and the other part (the right part) of the display element DE3. Thus, in the pixel PX1, the light-shielding layer 20 is formed to expose part of each of the display elements DE1, DE2, and DE3.

In the same manner as in the pixel PX1, in the pixel PX2, the light-shielding layer 20 is provided between the display element DE1 and the display element DE2 and between the display element DE1 and the display element DE3. The opening OP1 located on the left side of the pixel PX2 overlaps a part of the display element DE1. The opening OP2 located on the right side of the pixel PX2 overlaps a part of the display element DE2 and a part of the display element DE3.

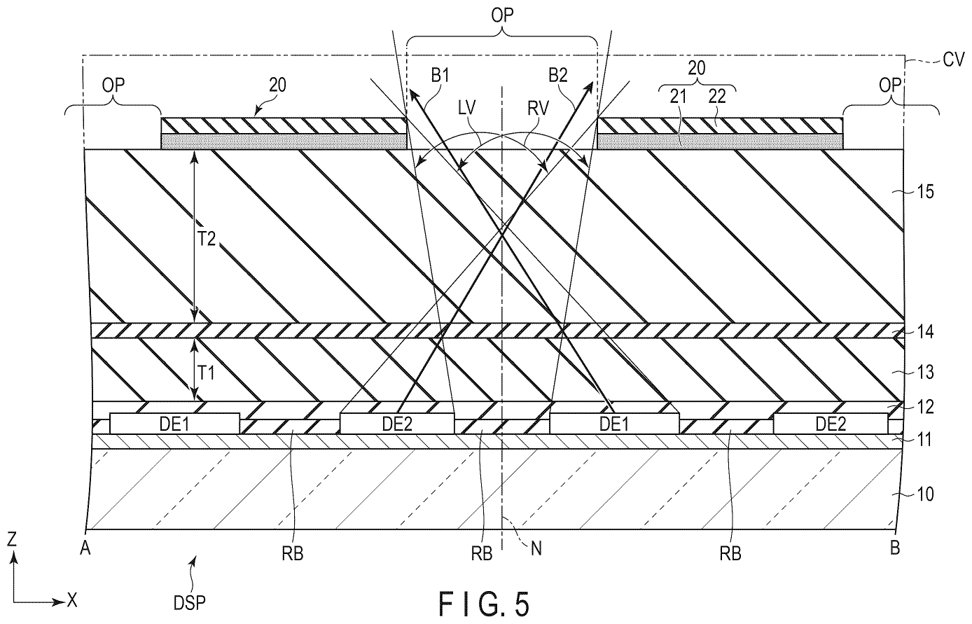

FIG. 5 is a schematic cross-sectional view of the display device DSP along the A-B line of FIG. 4.

A circuit layer 11 is provided on the substrate 10. The circuit layer 11 includes various circuits such as the pixel circuits 1 shown in FIG. 1, various lines such as the scanning line GL, the signal line SL, and the power line PL, and various insulating layers.

The display elements DE1 and DE2 are provided on the circuit layer 11. The display element DE3 (not shown) is also provided on the circuit layer 11. The rib RB is provided on the circuit layer 11 to separate the display elements DE1, DE2, and DE3 from each other. The rib RB is formed of, for example, an organic insulating material but may be formed of an inorganic insulating material.

The sealing layer 12 continuously covers the display elements DE1, DE2, and DE3. For example, the sealing layer 12 is formed of an inorganic insulating material such as a silicon nitride (SiNx), a silicon oxide (SiOx), and a silicon oxynitride (SiON).

A transparent resin layer 13 is provided on the sealing layer 12. The resin layer 13 is formed to planarize unevenness caused by the display elements DE1, DE2, and DE3.

An inorganic insulating layer 14 is provided on the resin layer 13. The inorganic insulating layer 14 is formed of the same inorganic insulating material as the sealing layer 12.

A transparent organic insulating layer 15 is located above the display elements DE1, DE2, and DE3 and is provided on the inorganic insulating layer 14. A thickness T2 of the organic insulating layer 15 is greater than a thickness T1 of the resin layer 13 (T1<T2).

The light-shielding layer 20 is provided on the organic insulating layer 15. The light-shielding layer 20 is a stacked layer body including a first layer 21 located on the organic insulating layer 15 and a second layer 22 located on the first layer 21. The first layer 21 and the second layer 22 are formed of mutually different materials.

The first layer 21 is a black layer having an extremely low reflectance over substantially the entire visible light range. The first layer 21 may be a metal layer or a resin layer containing a pigment.

The second layer 22 functions as a wavelength-cut layer having an extremely low reflectance in a specific wavelength range within the visible light range. The second layer 22 is a colored layer colored in the first color within the visible light range. For example, the second layer 22 is a colored layer colored in one of red, green, and blue. Alternatively, the second layer 22 may be a colored layer colored in one of cyan, magenta, and yellow.

A desirable combination of the first layer 21 and the second layer 22 aligns a wavelength range where the first layer 21 has a relatively higher reflectance in its spectral reflectance with a wavelength range where the second layer 22 has an extremely low reflectance in its spectral reflectance.

The following describes specific examples. When the spectral reflectance of the first layer 21 exhibits a relatively high reflectance in the blue wavelength range, reflected light from the first layer 21 contains a blue component. In such a case, as the second layer 22, it is desirable to apply a colored layer having an extremely low reflectance in the blue wavelength range. For example, the second layer 22 is desirable a red colored layer.

In another example, when reflected light from the first layer 21 contains a magenta component, the second layer 22 is desirable a green colored layer.

The organic insulating layer 15 and the light-shielding layer 20 are covered by a cover member CV indicated by a two-dot chain line. The cover member CV includes, for example, a transparent protective film, a circular polarizer for anti-reflection, and a cover glass.

The following describes one function of the display device DSP.

The following mainly describes on the opening OP located in the center of figure. This opening OP overlaps the left part of the display element DE1 and the right part of the display element DE2. When the display element DE1 emits light, a light beam B1 within a range LV that can pass through the opening OP can be observed, among light beams emitted from the display element DE1. When the display element DE2 emits light, a light beam B2 within a range RV that can pass through the opening OP can be observed, among light beams emitted from the display element DE2. Thus, providing the light-shielding layer 20 limits an observable range of light beams emitted from each of the display elements DE1 and DE2.

At a viewing position inclined to the left side with respect to a normal N of the substrate 10, the light beams B1 emitted from the display element DE1 can be observed mainly, through the opening OP. At a viewing position inclined to the right side with respect to the normal N, the light beams B2 emitted from the display element DE2 can be observed mainly, through the opening OP. At other openings OP as well, some of the light beams emitted from each of the light emitting element are permitted to pass.

Accordingly, a user who observes the display device DSP at an oblique direction inclined to the left side with respect to the normal N can observe the first image as a collection of the light beams B1 respectively emitted from the plurality of light emitting elements. A user who observes the display device DSP at an oblique direction inclined to the right side with respect to the normal N can observe the second image as a collection of the light beams B2 respectively emitted from the plurality of light emitting elements. For example, the first image and the second image are different images. Thus, the display device DSP has only one display area DA but can display mutually different images toward two oblique directions.

To achieve such light beam control, the light-shielding layer 20 is formed as a stacked layer body including the first layer 21 and the second layer 22 formed of mutually different materials. As described above, suitable combinations with desirable spectral reflectance are applied to the first layer 21 and the second layer 22. Thus, when the display device DSP is used under an environment where external light is incident upon the display device DSP, coloring due to undesirable reflection of the light-shielding layer 20 is suppressed. Thus, the display quality of images displayed in the display area DA can be increased.

Next, the following describes several other modified examples of the configuration example 1.

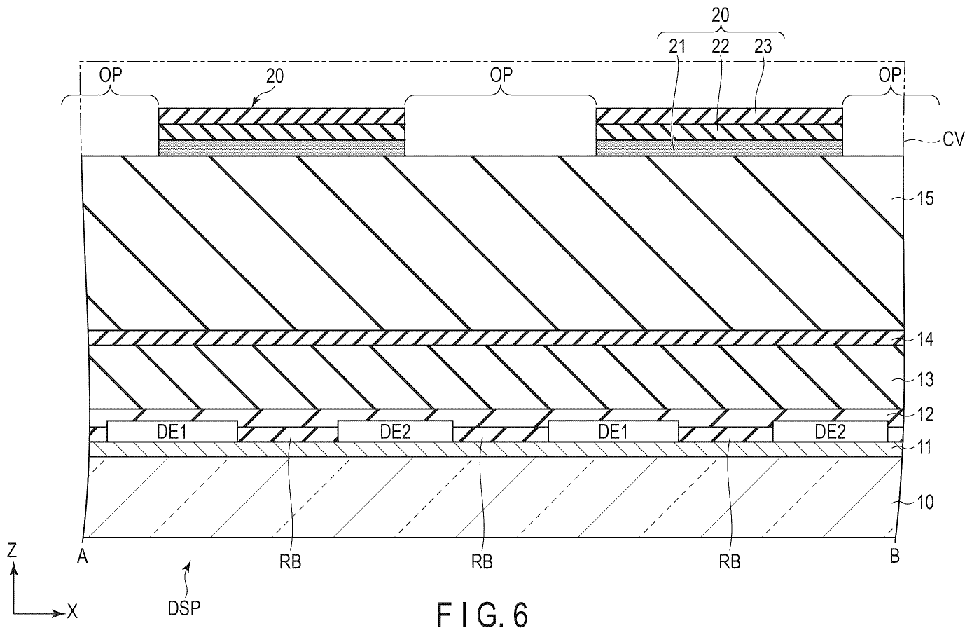

FIG. 6 is a schematic cross-sectional view of the modified example 1.

The modified example 1 shown in FIG. 6 differs from the example shown in FIG. 5 in that the light-shielding layer 20 includes a plurality of colored layers. Other components in the modified example 1 are the same as those shown in FIG. 5. These same components are denoted by the same reference numerals and their overlapping descriptions are omitted.

The light-shielding layer 20 is a stacked layer body including the first layer 21 located on the organic insulating layer 15, the second layer 22 located on the first layer 21, and a third layer 23 located on the second layer 22. The first layer 21, the second layer 22, and the third layer 23 are formed of mutually different materials.

For example, the first layer 21 is a black layer having an extremely low reflectance over substantially the entire visible light range. The second layer 22 is a colored layer colored in the first color. The third layer 23 is a colored layer colored in the second color different from the first color. A combination of the second layer 22 and the third layer 23 is appropriately determined according to the spectral reflectance of the first layer 21.

In one example, when reflected light of the first layer 21 contains a magenta component, it is desirable to apply a red colored layer as the second layer 22, and it is desirable to apply a blue colored layer as the third layer 23.

The light-shielding layer 20 configured as the stacked layer body of the black layer and the plurality of colored layers in this manner can suppress undesirable external-light reflection by the light-shielding layer 20. Thus, the modified example 1 can achieve the same effects as those described above.

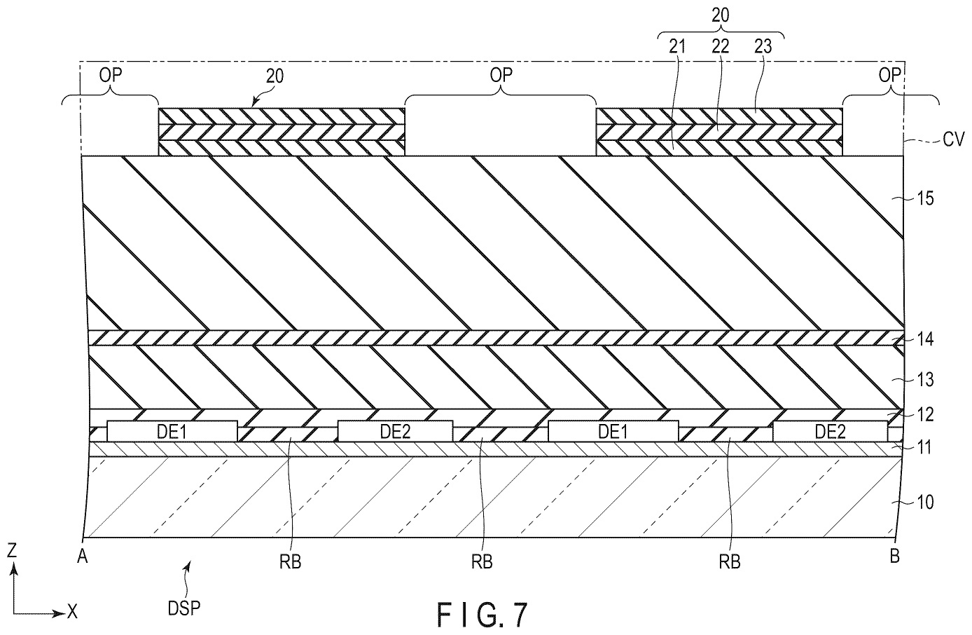

FIG. 7 is a schematic cross-sectional view of the modified example 2.

The modified example 2 shown in FIG. 7 differs from the example shown in FIG. 5 in that the light-shielding layer 20 includes the plurality of colored layers instead of a black layer. Other components in the modified example 2 are the same as those shown in FIG. 5. These same components are denoted by the same reference numerals and their overlapping descriptions are omitted.

The light-shielding layer 20 is a stacked layer body including the first layer 21 located on the organic insulating layer 15, the second layer 22 located on the first layer 21, and the third layer 23 located on the second layer 22. The first layer 21, the second layer 22, and the third layer 23 are colored layers formed of mutually different materials.

The first layer 21 is a colored layer colored in the first color. The second layer 22 is a colored layer colored in the second color different from the first color. The third layer 23 is a colored layer colored in the third color different from the first color and the second color. For example, the first layer 21 is a blue colored layer, the second layer 22 is a green colored layer, and the third layer 23 is a red colored layer. This combination of the blue colored layer, the green colored layer, and the red colored layer has an extremely low reflectance over substantially the entire visible light range. The light-shielding layer 20 in the modified example 2 functions as the light-shielding layer equivalent to a black layer. The stacking order of the colored layers is not limited to the example shown here.

Thus, the modified example 2 can achieve the same effects as those described above.

Next, the following describes the configuration example 2. In each of the embodiments described below, the same constituent elements as in the configuration example 1 are denoted by the same reference numerals and their overlapping explanations are omitted in some cases.

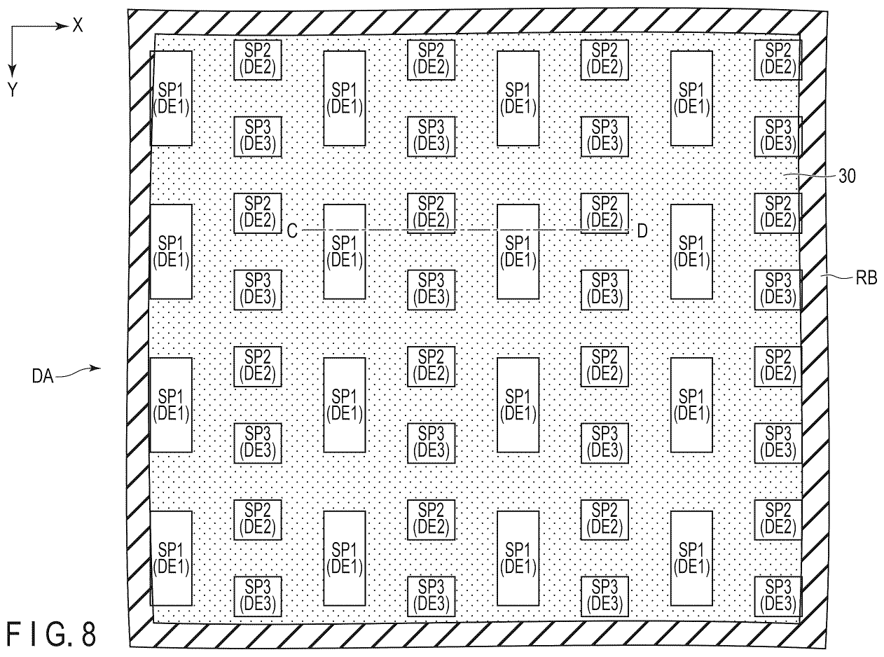

FIG. 8 is a plan view for describing the configuration example 2.

In addition to the light-shielding layer 20 described in the configuration example 1, the configuration example 2 includes a light-shielding layer 30. FIG. 8 omits the illustration of the light-shielding layer 20. For example, the light-shielding layer 20 has the same shape as the one described with reference to FIG. 4.

The light-shielding layer 30 is provided to overlap the display area DA in plan view. The light-shielding layer 30 is formed into a grating shape overlapping the rib RB. That is, the light-shielding layer 30 has the respective openings overlapping the apertures AP1, AP2, and AP3 of the rib RB described with reference to FIG. 2. The display elements DE1, DE2, and DE3 overlap the openings of the light-shielding layer 30.

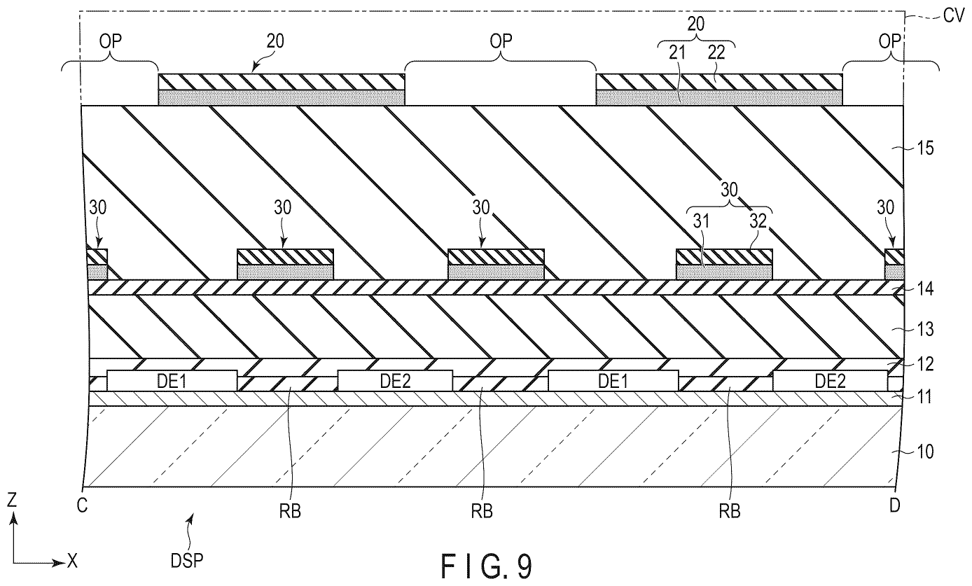

FIG. 9 is a schematic cross-sectional view of the display device DSP along the C-D line of FIG. 8.

The light-shielding layer 30 is located directly above the rib RB, is provided on the inorganic insulating layer 14, and is covered with the organic insulating layer 15. Part of the light-shielding layer 30 overlaps the opening OP.

The light-shielding layer 30 is a stacked layer body including a fourth layer 31 located on the inorganic insulating layer 14 and a fifth layer 32 located on the fourth layer 31. The fourth layer 31 and the fifth layer 32 are formed of mutually different materials.

The fourth layer 31 is a black layer having an extremely low reflectance over substantially the entire visible light range. The fourth layer 31 may be a metal layer or a resin layer containing a pigment.

The fifth layer 32 functions as a wavelength-cut layer having an extremely low reflectance in a specific wavelength range within the visible light range. The fifth layer 32 is a colored layer colored in a first color within the visible light range. For example, the fifth layer 32 is a colored layer colored in red, green, blue, cyan, magenta, or yellow.

A desirable combination of the fourth layer 31 and the fifth layer 32 is similar to the desirable combination of the first layer 21 and the second layer 22 described in the configuration example 1.

In the configuration example 2 including the light-shielding layer 30, the observable range of light beams emitted from each of the display elements DE1, DE2, and DE3 can be restricted further than the configuration example 1. In addition, when the display device DSP is viewed at an oblique direction, undesirable reflection at the light-shielding layer 30 is suppressed. Thus, the display quality of images displayed in the display area DA can be increased.

In the illustrated example, the light-shielding layer 20 is a stacked layer body of the first layer 21 and the second layer 22, the first layer 21 and the fourth layer 31 are formed of the same material, and the second layer 22 and the fifth layer 32 are formed of the same material. Materials necessary to form the light-shielding layer 20 and the light-shielding layer 30 are thereby reduced in the manufacturing of the display device DSP, which suppresses an increase in manufacturing cost.

Next, the following describes several other modified examples of the configuration example 2.

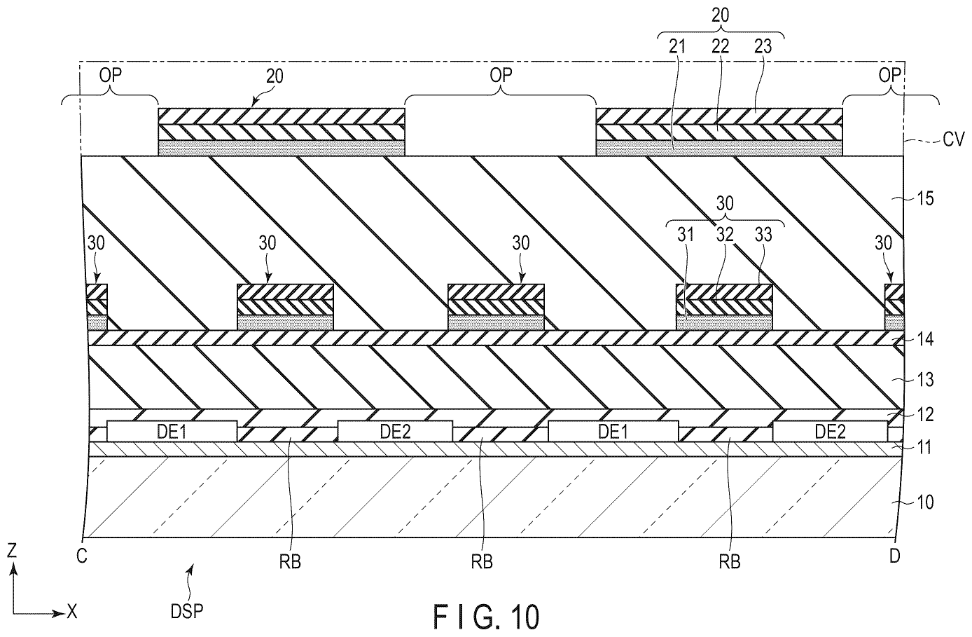

FIG. 10 is a schematic cross-sectional view of the modified example 3.

The modified example 3 shown in FIG. 10 differs from the example shown in FIG. 9 in that the light-shielding layer 30 includes a plurality of colored layers. Other components in the modified example 3 are the same as those shown in FIG. 9. These same components are denoted by the same reference numerals and their overlapping descriptions are omitted.

The light-shielding layer 30 is a stacked layer body including the fourth layer 31 located on the inorganic insulating layer 14, the fifth layer 32 located on the fourth layer 31, and a sixth layer 33 located on the fifth layer 32. The fourth layer 31, the fifth layer 32, and the sixth layer 33 are formed of mutually different materials.

For example, the fourth layer 31 is a black layer having an extremely low reflectance over substantially the entire visible light range. The fifth layer 32 is a colored layer colored in the first color. The sixth layer 33 is a colored layer colored in the second color different from the first color. A combination of the fifth layer 32 and the sixth layer 33 is appropriately determined according to the spectral reflectance of the fourth layer 31.

In the illustrated example, the light-shielding layer 20 is a stacked layer body of the first layer 21, the second layer 22, and the third layer 23. The first layer 21 and the fourth layer 31 are formed of the same material, the second layer 22 and the fifth layer 32 are formed of the same material, and the third layer 23 and the sixth layer 33 are formed of the same material.

Thus, the modified example 3 can achieve the same effects as those described above.

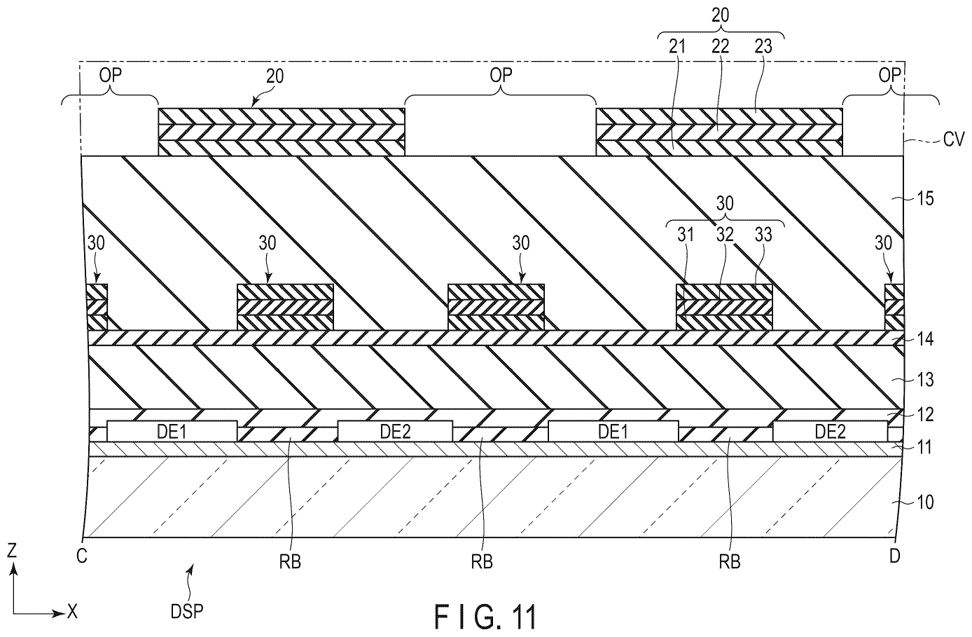

FIG. 11 is a schematic cross-sectional view of the modified example 4.

The modified example 4 shown in FIG. 11 differs from the example shown in FIG. 9 in that the light-shielding layer 30 includes the plurality of colored layers instead of a black layer. Other components in the modified example 4 are the same as those shown in FIG. 9. These same components are denoted by the same reference numerals and their overlapping descriptions are omitted.

The light-shielding layer 30 is a stacked layer body including the fourth layer 31 located on the inorganic insulating layer 14, the fifth layer 32 located on the fourth layer 31, and the sixth layer 33 located on the fifth layer 32. The fourth layer 31, the fifth layer 32, and the sixth layer 33 are colored layers formed of mutually different materials.

The fourth layer 31 is a colored layer colored in the first color. The fifth layer 32 is a colored layer colored in the second color different from the first color. The sixth layer 33 is a colored layer colored in the third color different from the first color and the second color. For example, the fourth layer 31 is a blue colored layer, the fifth layer 32 is a green colored layer, and the sixth layer 33 is a red colored layer. This combination of the blue colored layer, the green colored layer, and the red colored layer has an extremely low reflectance over substantially the entire visible light range. The light-shielding layer 30 in the modified example 4 functions as the light-shielding layer equivalent to a black layer. The stacking order of the colored layers is not limited to the example shown here.

In the illustrated example, the light-shielding layer 20 is a stacked layer body of the first layer 21, the second layer 22, and the third layer 23. The first layer 21 and the fourth layer 31 are formed of the same material, the second layer 22 and the fifth layer 32 are formed of the same material, and the third layer 23 and the sixth layer 33 are formed of the same material.

Thus, the modified example 4 can achieve the same effects as those described above.

In the examples shown in FIG. 9 to FIG. 11, material combinations constituting the light-shielding layer 30 may differ from material combinations constituting the light-shielding layer 20. For example, the light-shielding layer 30 shown in FIG. 9 may be combined with the light-shielding layer 20 shown in FIG. 6 or FIG. 7. Alternatively, the light-shielding layer 30 shown in FIG. 10 may be combined with the light-shielding layer 20 shown in FIG. 5 or FIG. 7. Alternatively, the light-shielding layer 30 shown in FIG. 11 may be combined with the light-shielding layer 20 shown in FIG. 5 or FIG. 6.

Next, the following describes the configuration example 3.

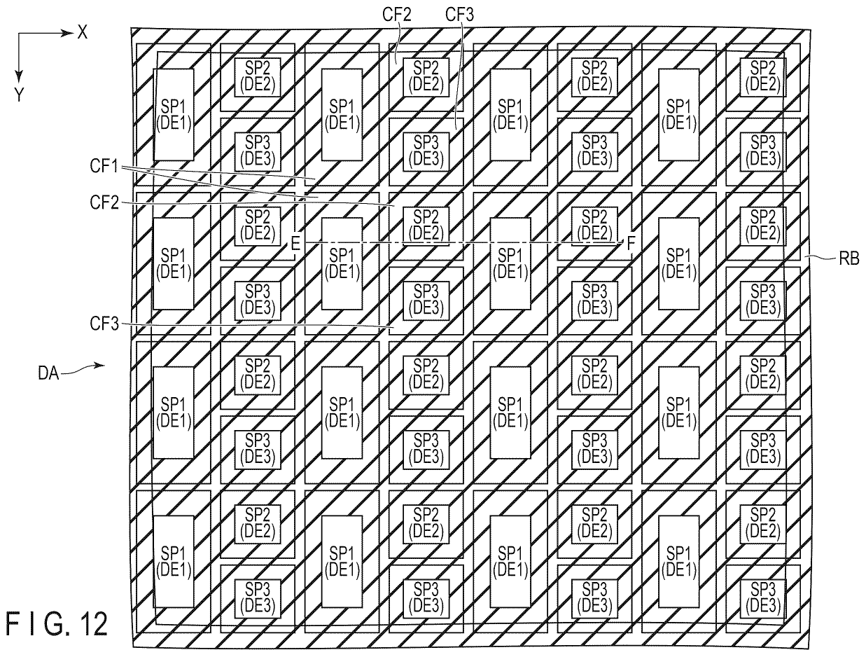

FIG. 12 is a plan view for describing the configuration example 3.

In addition to the light-shielding layer 20 described in the configuration example 1, the configuration example 3 comprises color filters CF1, CF2, and CF3. FIG. 12 omits the illustration of the light-shielding layer 20. For example, the light-shielding layer 20 has the same shape as the one described with reference to FIG. 4.

The color filter CF1 is provided to overlap the display element DE1 in plan view. When the display element DE1 is configured to display the first color, the color filter CF1 is colored in the first color (for example, blue).

The color filter CF2 is provided to overlap the display element DE2 in plan view. When the display element DE2 is configured to display the second color, the color filter CF2 is colored in the second color (for example, green).

The color filter CF3 is provided to overlap the display element DE3 in plan view. When the display element DE3 is configured to display the third color, the color filter CF3 is colored in the third color (for example, red).

In the illustrated example, the color filters CF1, CF2, and CF3 are separated from each other. Two or all three of the color filters CF1, CF2, and CF3 may contact each other. An edge of each of the color filters CF1, CF2, and CF3 overlaps the rib RB along its entire circumference in plan view.

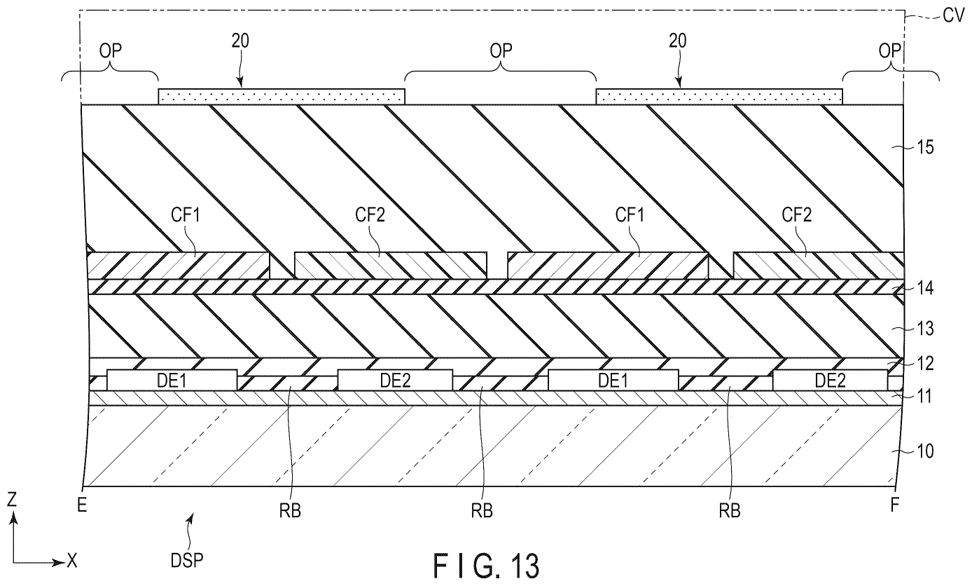

FIG. 13 is a schematic cross-sectional view of the display device DSP along the E-F line of FIG. 12.

The color filter CF1 is located directly above the display element DE1, is provided on the inorganic insulating layer 14, and is covered with the organic insulating layer 15. The color filter CF2 is located directly above the display element DE2, is provided on the inorganic insulating layer 14, and is covered with the organic insulating layer 15. Though not illustrated, the color filter CF3 is located directly above the display element DE3, is provided on the inorganic insulating layer 14, and is covered with the organic insulating layer 15. Part of each of the color filters CF1, CF2, and CF3 overlaps the opening OP.

The light-shielding layer 20 may be the stacked layer body of the first layer 21 which is the black layer and the second layer 22 which is the colored layer, as shown in FIG. 5. Alternatively, the light-shielding layer 20 may be the stacked layer body of the first layer 21 which is the black layer and the second and third layers 22 and 23 which are the colored layer, as shown in FIG. 6. Alternatively, the light-shielding layer 20 may be the stacked layer body of the first to third layers 21, 22, and 23 which are the colored layer, as shown in FIG. 7.

In the configuration example 3 comprising these color filters CF1, CF2, and CF3, part of external light traveling toward the display device DSP is absorbed by the color filters CF1, CF2, and CF3. In contrast, light of the first color emitted from the display element DE1 passes through the color filter CF1. Similarly, light of the second color emitted from the display element DE2 passes through the color filter CF2, and light of the third color emitted from the display element DE3 passes through the color filter CF3. Undesirable reflection of external light is thereby suppressed. Thus, display quality of images displayed in the display area DA can be improved. Further, a circular polarizer for anti-reflection on the cover member CV can be omitted.

Next, the following describes the configuration example 4.

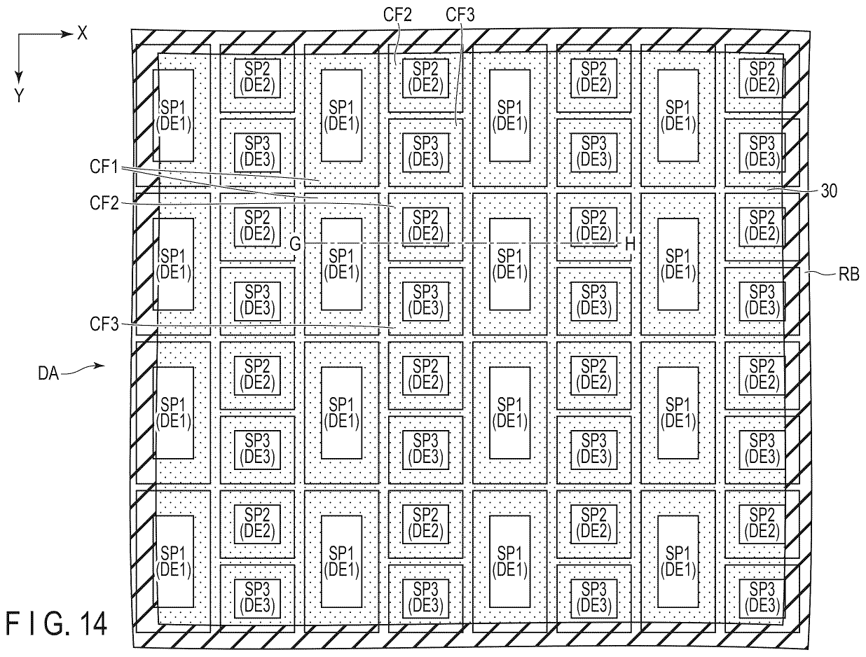

FIG. 14 is a plan view for describing the configuration example 4.

In addition to the light-shielding layer 20 described in the configuration example 1 and the color filters CF1, CF2, and CF3 described in the configuration example 3, the configuration example 4 includes the light-shielding layer 30. FIG. 14 omits the illustration of the light-shielding layer 20. For example, the light-shielding layer 20 has the same shape as the one described with reference to FIG. 4.

The light-shielding layer 30 is provided to overlap the display area DA in plan view. The light-shielding layer 30 is formed into a grating shape overlapping the rib RB. That is, the light-shielding layer 30 has the respective openings overlapping the apertures AP1, AP2, and AP3 of the rib RB described with reference to FIG. 2.

The light-shielding layer 30 is also provided between the color filter CF1 and the color filter CF2, between the color filter CF3 and the color filter CF1, and between the color filter CF3 and the color filter CF2.

The display element DE1 overlaps an opening of the light-shielding layer 30 and overlaps the color filter CF1. The display element DE2 overlaps an opening of the light-shielding layer 30 and overlaps the color filter CF2. The display element DE3 overlaps an opening of the light-shielding layer 30 and overlaps the color filter CF3.

The edge of each of the color filters CF1, CF2, and CF3 overlaps the light-shielding layer 30 along its entire circumference in plan view.

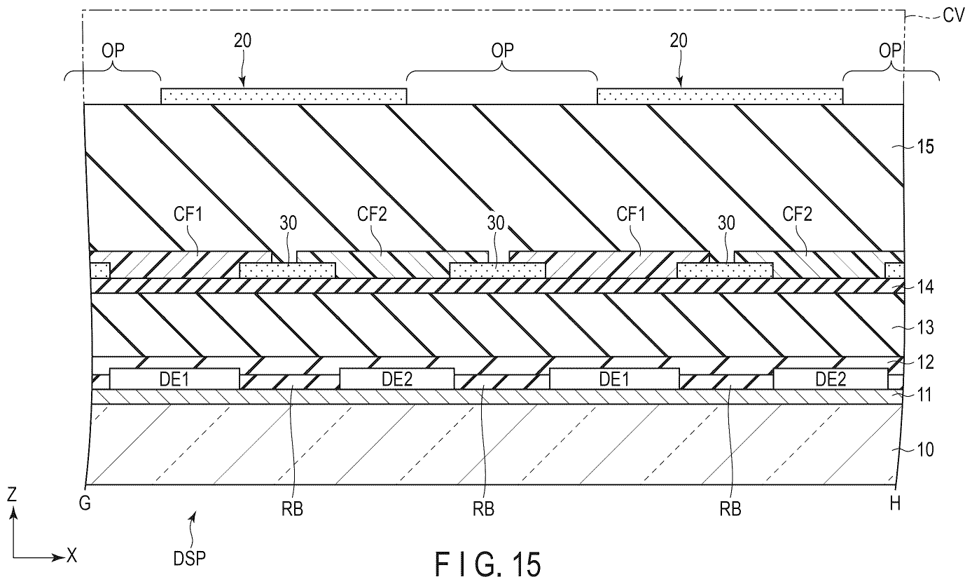

FIG. 15 is a schematic cross-sectional view of the display device DSP along the G-H line of FIG. 14.

The light-shielding layer 30 is located directly above the rib RB, is provided on the inorganic insulating layer 14, and is covered with the organic insulating layer 15. Part of the light-shielding layer 30 overlaps the opening OP.

The light-shielding layer 30 may be the stacked layer body of the fourth layer 31 which is the black layer and the fifth layer 32 which is the colored layer, as shown in FIG. 9. Alternatively, the light-shielding layer 30 may be the stacked layer body of the fourth layer 31 which is the black layer and the fifth and the sixth layers 32 and 33 which are the colored layer, as shown in FIG. 10. Alternatively, the light-shielding layer 30 may be the stacked layer body of the fourth to sixth layers 31, 32, and 33 which are the colored layer, as shown in FIG. 11.

The light-shielding layer 20 may be the stacked layer body of the first layer 21 which is the black layer and the second layer 22 which is the colored layer, as shown in FIG. 5. Alternatively, the light-shielding layer 20 may be the stacked layer body of the first layer 21 which is the black layer and the second and third layers 22 and 23 which are the colored layer, as shown in FIG. 6. Alternatively, the light-shielding layer 20 may be the stacked layer body of the first to third layers 21, 22, and 23 which are the colored layer, as shown in FIG. 7.

The color filter CF1 is located directly above the display element DE1, is provided on the inorganic insulating layer 14, and is covered with the organic insulating layer 15. The color filter CF2 is located directly above the display element DE2, is provided on the inorganic insulating layer 14, and is covered with the organic insulating layer 15. Though not illustrated, the color filter CF3 is located directly above the display element DE3, is provided on the inorganic insulating layer 14, and is covered with the organic insulating layer 15. Part of each of the color filters CF1, CF2, and CF3 overlaps the opening OP. The edge of each of the color filters CF1, CF2, and CF3 overlaps the light-shielding layer 30.

The configuration example 4 can achieve the same effects as those of the configuration example 2 comprising the light-shielding layer 30 and the configuration example 3 comprising the color filters CF1, CF2, and CF3.

Next, the following describes the configuration example 5.

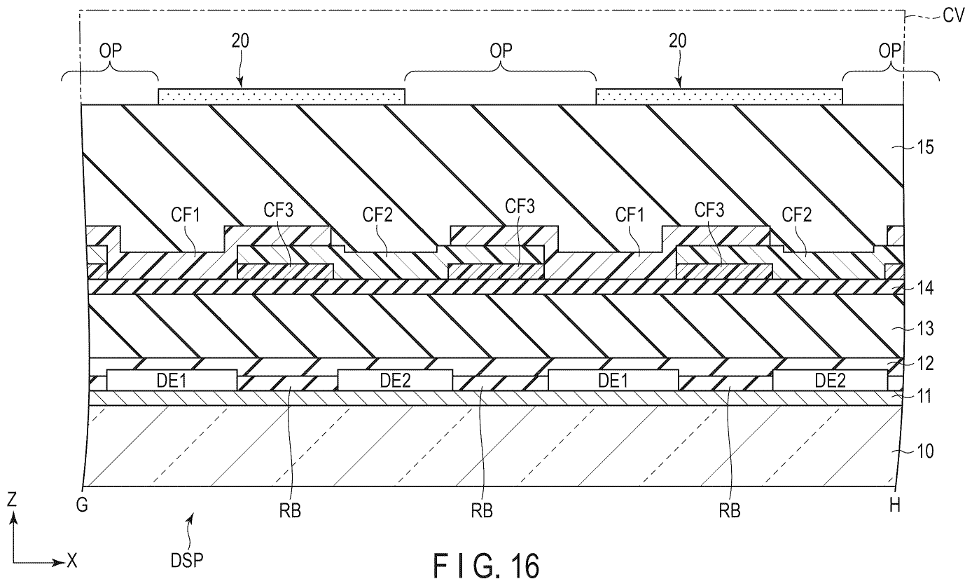

FIG. 16 is a schematic cross-sectional view of the configuration example 5.

The configuration example 5 shown in FIG. 16 differs from the configuration example 4 shown in FIG. 15 in that, instead of the light-shielding layer 30, the stacked layer body of the color filters CF1, CF2, and CF3 is provided in an area overlapping the rib RB.

The color filter CF3 is located directly above the display element DE3 (not shown), is provided on the inorganic insulating layer 14, and extends directly above the rib RB. The color filter CF2 is located directly above the display element DE2 and is provided on the inorganic insulating layer 14. The color filter CF2 also extends directly above the rib RB and is provided on the color filter CF3. The color filter CF1 is located directly above the display element DE1 and is provided on the inorganic insulating layer 14. The color filter CF1 also extends directly above the rib RB and is provided on the color filter CF2. That is, directly above the rib RB, the color filters CF3, CF2, and CF1 are stacked in this order. The stacking order of the color filters CF1, CF2, and CF3 is not limited to the illustrated example.

The color filter CF1 is colored in the first color (for example, blue). The color filter CF2 is colored in the second color (for example, green). The color filter CF3 is colored in the third color (for example, red).

In the same manner as the modified example 4 described with reference to FIG. 11, the combination of the blue colored layer, the green colored layer, and the red colored layer has an extremely low reflectance over substantially the entire visible light range. The stacked layer body of the color filters CF1, CF2, and CF3 formed directly above the rib RB therefore functions as a light-shielding layer equivalent to a black layer.

Further, the light-shielding layer 20 may be the stacked layer body of the first layer 21 which is the black layer and the second layer 22 which is the colored layer, as shown in FIG. 5. Alternatively, the light-shielding layer 20 may be the stacked layer body of the first layer 21 which is the black layer and the second and third layers 22 and 23 which are the colored layer, as shown in FIG. 6. Alternatively, the light-shielding layer 20 may be the stacked layer body of the first to third layers 21, 22, and 23 which are the colored layer, as shown in FIG. 7.

This configuration example 5 can achieve the above effects. Further, the stacked layer body of the color filters CF1, CF2, and CF3 in the configuration example 5 can achieve light beam control equivalent to that of the light-shielding layer 30. Further, the omission of the light-shielding layer 30 in the configuration example 5 can reduce materials required to form the light-shielding layer 30, which reduces manufacturing cost.

Next, the following describes variations common to the configuration examples 1 to 5. In each of the variation described below, the display element DE1 of the subpixel SP1, the display element DE2 of the subpixel SP2, the display element DE3 of the subpixel SP3, and the light-shielding layer 20 are illustrated, but the other components are not illustrated.

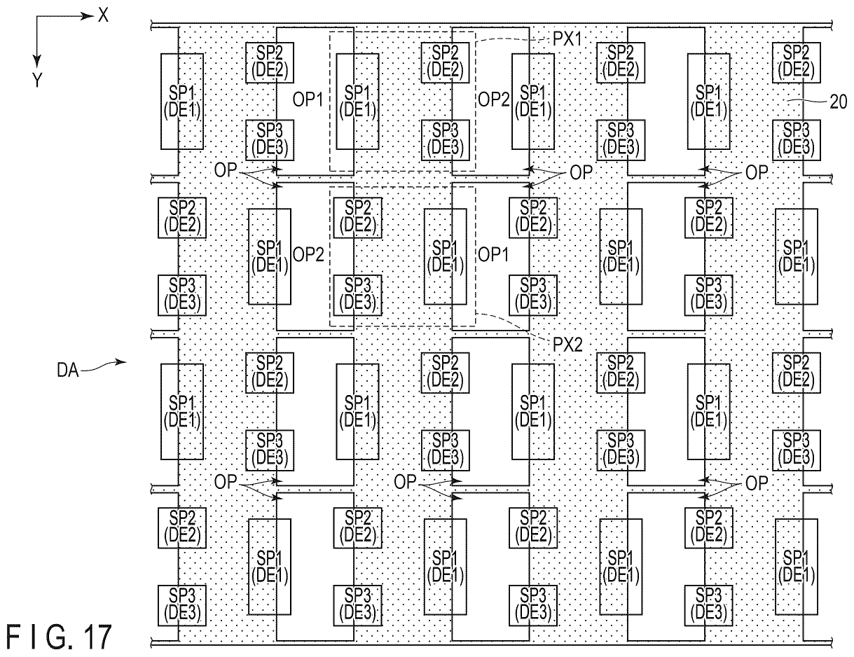

FIG. 17 is a plan view for describing the variation 1.

In the second direction Y of the display area DA, the subpixel SP1, the subpixel SP2, and the subpixel SP3 (or the display element DE1, the display element DE2, and the display element DE3) are arranged in sequence. Further, in the first direction X, the subpixel SP1 and the subpixel SP2 (or the display element DE1 and the display element DE2) are alternately arranged, and the subpixel SP1 and the subpixel SP3 (or the display element DE1 and the display element DE3) are alternately arranged.

The following mainly describes on the two pixels PX1 and PX2 arranged in the second direction Y of the plurality of pixels arranged in the display area DA.

The display element DE1 of the pixel PX1, the display element DE2 of the pixel PX2, and the display element DE3 of the pixel PX2 are arranged in the second direction Y. The display element DE2 of the pixel PX1, the display element DE3 of the pixel PX1, and the display element DE1 of the pixel PX2 are arranged in the second direction Y.

In the pixel PX1, the light-shielding layer 20 overlaps a part (the right part) of the display element DE1, a part (the left part) of the display element DE2, and a part (the left part) of the display element DE3. The opening OP1 is located on the left side of the pixel PX1 and overlaps the other part (left part) of the display element DE1. The opening OP2 is located on the right side of the pixel PX1 and overlaps the other part (the right part) of the display element DE2 and the other part (the right part) of the display element DE3.

In the pixel PX2, the light-shielding layer 20 overlaps a part (the left part) of the display element DE1, a part (the right part) of the display element DE2, and a part (the right part) of the display element DE3. The opening OP1 is located on the right side of the pixel PX2 and overlaps the other part (the right part) of the display element DE1. The opening OP2 is located on the left side of the pixel PX2 and overlaps the other part (the left part) of the display element DE2 and the other part (the left part) of the display element DE3.

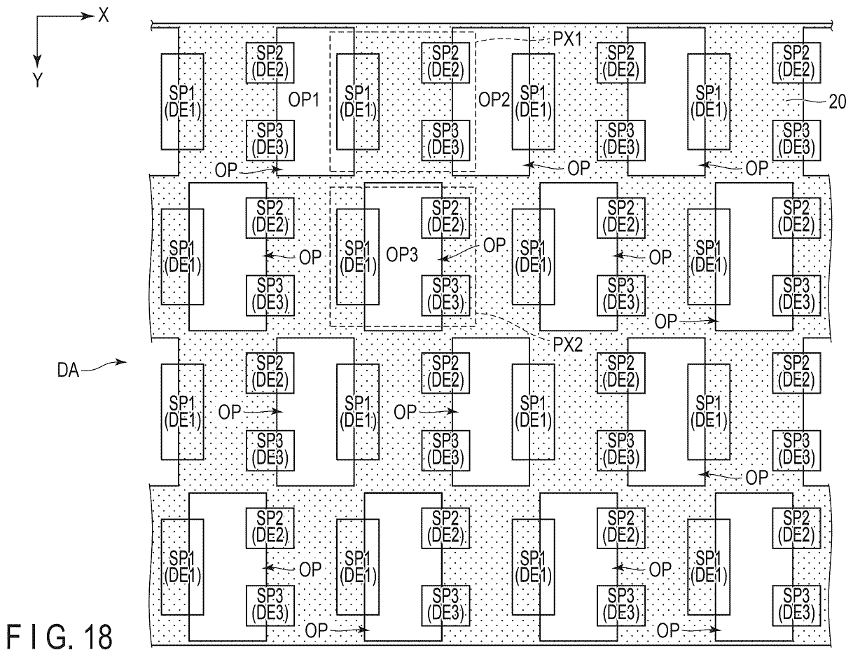

FIG. 18 is a plan view for describing the variation 2.

In the second direction Y of the display area DA, the plurality of subpixels SP1 (or the plurality of display elements DE1) are arranged in the second direction Y, and the subpixel SP2 and the subpixel SP3 (or the display element DE2 and the display element DE3) are alternately arranged. Further, in the first direction X, the subpixel SP1 and the subpixel SP2 (or the display element DE1 and the display element DE2) are alternately arranged, and the subpixel SP1 and the subpixel SP3 (or the display element DE1 and the display element DE3) are alternately arranged.

The following mainly describes on the two pixels PX1 and PX2 arranged in the second direction Y of the plurality of pixels arranged in the display area DA.

The display element DE1 of the pixel PX1 and the display element DE1 of the pixel PX2 are arranged in the second direction Y. The display element DE2 of the pixel PX1, the display element DE3 of the pixel PX1, the display element DE2 of the pixel PX2, and the display element DE3 of the pixel PX2 are arranged in the second direction Y.

In the pixel PX1, the light-shielding layer 20 overlaps a part (the right part) of the display element DE1, a part (the left part) of the display element DE2, and a part (the left part) of the display element DE3. The opening OP1 is located on the left side of the pixel PX1 and overlaps the other part (left part) of the display element DE1. The opening OP2 is located on the right side of the pixel PX1 and overlaps the other part (the right part) of the display element DE2 and the other part (the right part) of the display element DE3.

In the pixel PX2, the light-shielding layer 20 overlaps a part (the left part) of the display element DE1, a part (the right part) of the display element DE2, and a part (the right part) of the display element DE3. The opening OP3 is spaced apart from the openings OP1 and OP2 and is located substantially at the center of the pixel PX2. The opening OP3 overlaps the other part (the right part) of the display element DE1, the other part (the left part) of the display element DE2, and the other part (the left part) of the display element DE3.

In these variations 1 and 2, a user observing the display device DSP at an oblique direction to the left side with respect to the normal N can observe the first image as a collection of light beams respectively emitted from the display element DE1 of the pixel PX1 and from the display elements DE2 and DE3 of the pixel PX2. Further, a user observing the display device DSP at an oblique direction to the right side with respect to the normal N can observe the second image as a collection of light beams respectively emitted from the display elements DE2 and DE3 of the pixel PX1 and from the display element DE1 of the pixel PX2.

These variations 1 and 2 can be applicable to any of configuration examples 1 to 5.

Next, the following describes the configuration example 6.

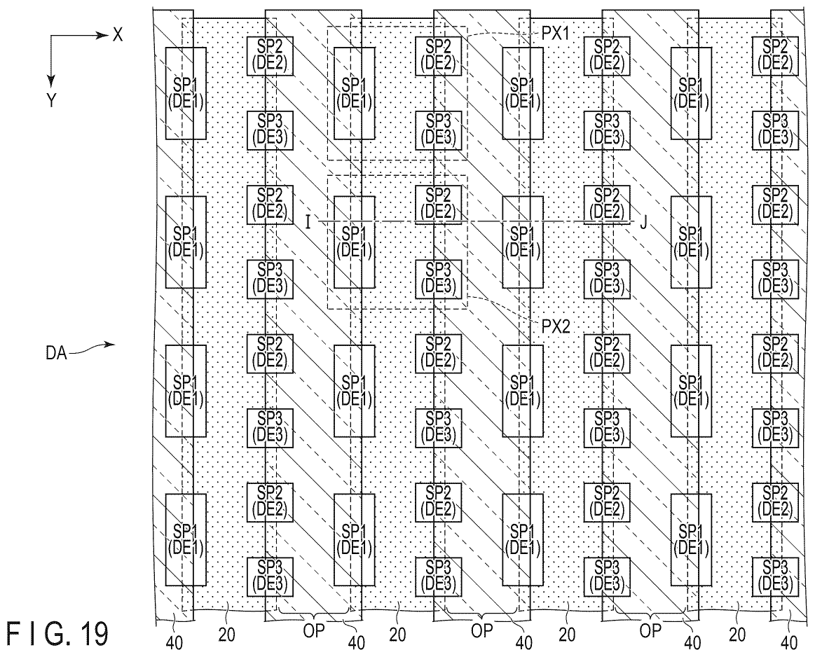

FIG. 19 is a plan view for describing the configuration example 6.

The configuration example 6 shown in FIG. 19 differs from the configuration example 1 shown in FIG. 4 in comprising a plurality of lenses 40. The lenses 40 are provided in the openings OP formed in the light-shielding layer 20. In the illustrated example, the plurality of lenses 40 each extend in the second direction Y and are arranged in the first direction X with interval. A width of the lens 40 along the first direction X is greater than a width of the opening OP along the first direction X. An edge of the lens 40 along the second direction Y overlaps the light-shielding layer 20.

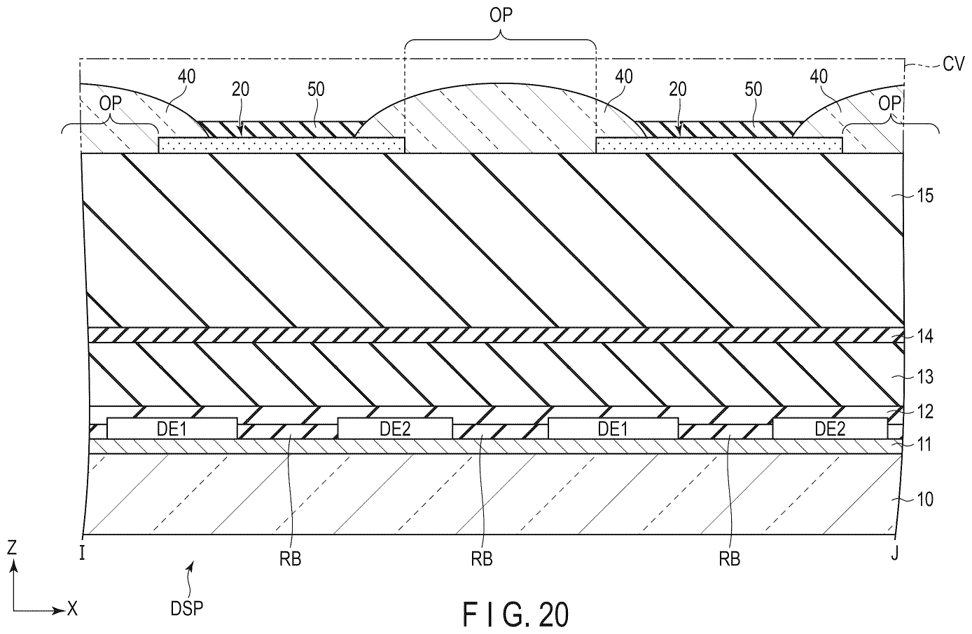

FIG. 20 is a schematic cross-sectional view of the display device DSP along the I-J line of FIG. 19.

The lens 40 is provided on the organic insulating layer 15 and overlaps the opening OP. The edge of the lens 40 is located on the light-shielding layer 20. As illustrated, the lens 40 is a plano-convex lens having a plane contacting the organic insulating layer 15 and a convex surface opposite to the plane.

A low-refractive-index layer 50 is formed of a material having a refractive index lower than that of the lens 40. The low-refractive-index layer 50 is provided on the light-shielding layer 20, covers the edge of the lens 40, and exposes the apex portion of the lens 40.

The cover member CV indicated by a two-dot chain line covers the lens 40 and the low-refractive-index layer 50. When the cover member CV is, for example, a circular polarizer, the lens 40 is covered with the adhesive of the circular polarizer. When a difference between the refractive index of the adhesive and the refractive index of the lens 40 is small, refraction effects produced by the lens 40 for light traveling in the oblique direction becomes insufficient. Thus, an area in the vicinity of the edge of the lens 40 is preferably covered with the low-refractive-index layer 50.

The detailed configuration of the light-shielding layer 20 is the same as the one described in the configuration example 1. That is, the light-shielding layer 20 may be the stacked layer body of the first layer 21 which is the black layer and the second layer 22 which is the colored layer, as shown in FIG. 5. Alternatively, the light-shielding layer 20 may be the stacked layer body of the first layer 21 which is the black layer and the second and third layers 22 and 23 which are the colored layer, as shown in FIG. 6. Alternatively, the light-shielding layer 20 may be the stacked layer body of the first to third layers 21, 22, and 23 which are the colored layer, as shown in FIG. 7.

The configuration example 6 can achieve the same effects of those of the configuration example 1 as well.

Next, the following describes the configuration example 7.

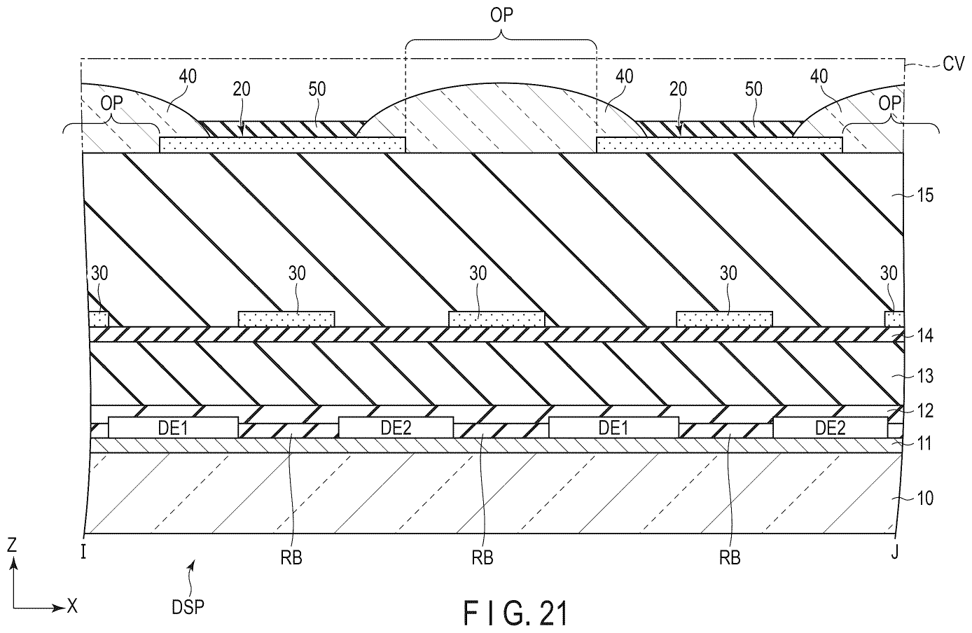

FIG. 21 is a schematic cross-sectional view of the configuration example 7.

The configuration example 7 shown in FIG. 21 differs from the configuration example 6 shown in FIG. 20 in comprising the light-shielding layer 30 in addition to the light-shielding layer 20. The planar shape of the light-shielding layer 30 is the same as the one described with reference to FIG. 8. The lens 40 overlaps part of the light-shielding layer 30.

The detailed configuration of the light-shielding layer 30 is the same as the one described in the configuration example 2. That is, the light-shielding layer 30 may be the stacked layer body of the fourth layer 31 which is the black layer and the fifth layer 32 which is the colored layer, as shown in FIG. 9. Alternatively, the light-shielding layer 30 may be the stacked layer body of the fourth layer 31 which is the black layer and the fifth and the sixth layers 32 and 33 which are the colored layer, as shown in FIG. 10. Alternatively, the light-shielding layer 30 may be the stacked layer body of the fourth to sixth layers 31, 32, and 33 which are the colored layer, as shown in FIG. 11.

Thus, the configuration example 7 can achieve the same effects as those described above.

Next, the following describes the configuration example 8.

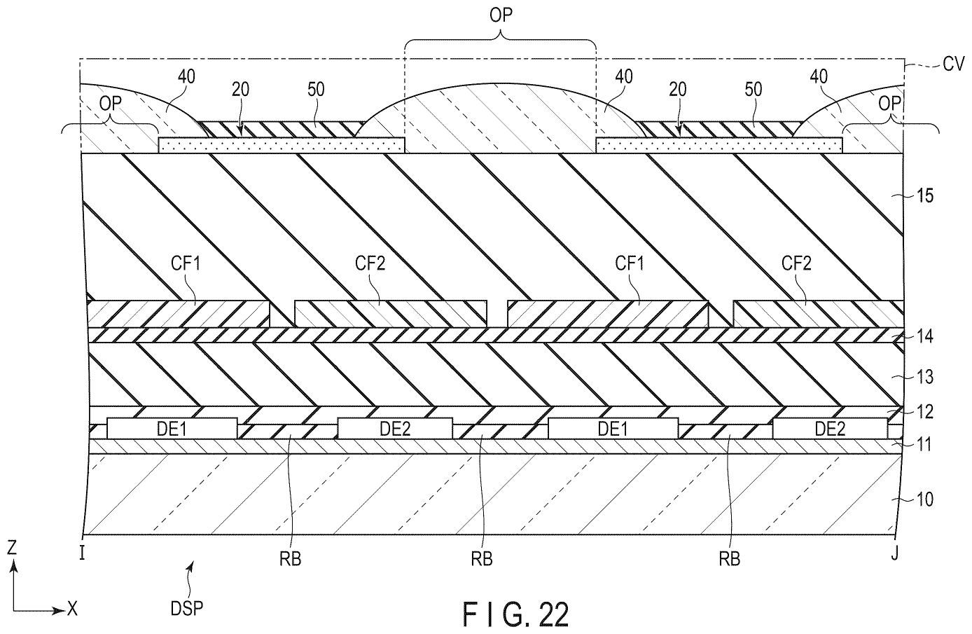

FIG. 22 is a plan view for describing the configuration example 8.

The configuration example 8 shown in FIG. 22 differs from the configuration example 6 shown in FIG. 20 in comprising the color filters CF1, CF2, and CF3 in addition to the light-shielding layer 20. The layout of the color filters CF1, CF2, and CF3 is as described, for example, with reference to FIG. 12. The details of each of the color filters CF1, CF2, and CF3 are the same as those described in the configuration example 3. The lens 40 overlaps part of each of the color filters CF1, CF2, and CF3.

Thus, the configuration example 8 can achieve the same effects as those described above.

Next, the following describes the configuration example 9.

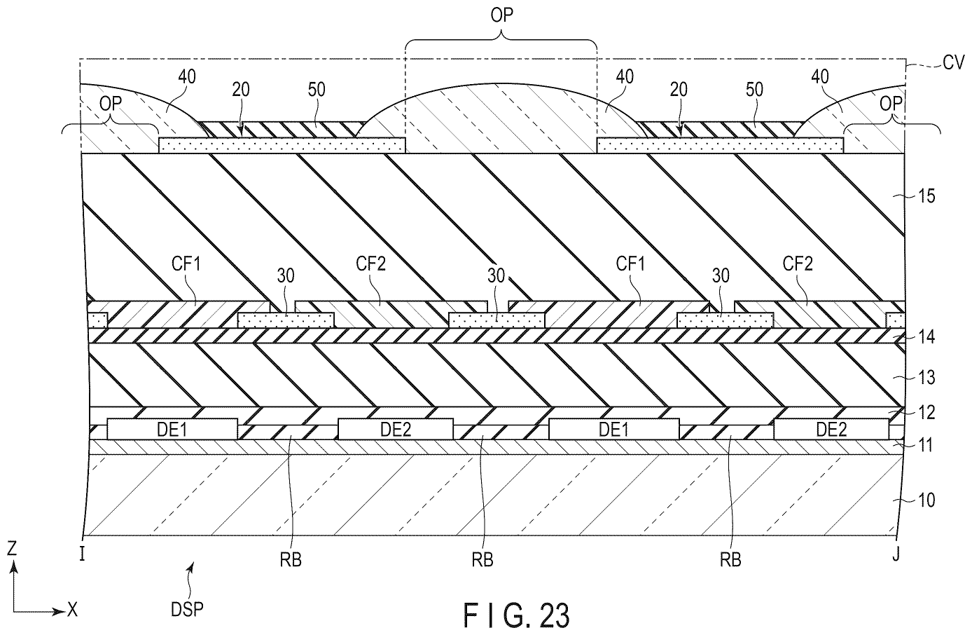

FIG. 23 is a plan view for describing the configuration example 9.

The configuration example 9 shown in FIG. 23 differs from the configuration example 8 shown in FIG. 22 in comprising the light-shielding layer 30. Details of the light-shielding layer 30 are the same as those described in the configuration example 2.

The configuration example 9 can achieve the same effects as those described above.

Next, the following describes the configuration example 10.

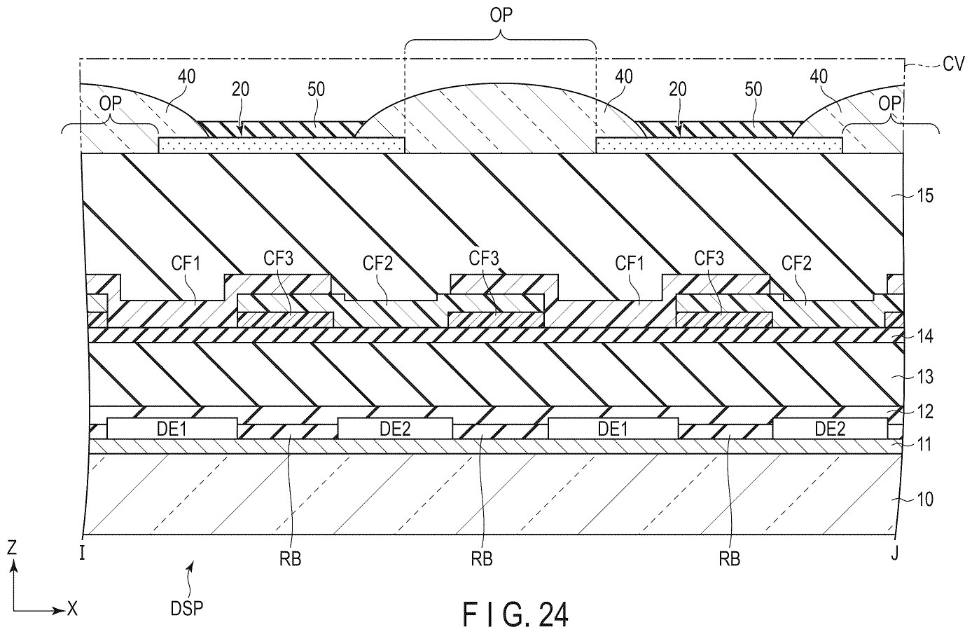

FIG. 24 is a plan view for describing the configuration example 10.

The configuration example 10 shown in FIG. 24 differs from the configuration example 9 shown in FIG. 23 in that, instead of the light-shielding layer 30, the stacked layer body of the color filters CF1, CF2, and CF3 is provided in an area overlapping the rib RB. The details of the stacked layer body of the color filters CF1, CF2, and CF3 are the same as those described in the configuration example 5.

The configuration example 10 can achieve the same effects as those described above.

Next, the following describes variations common to the configuration examples 6 to 10. In each of the variation described below, the display element DE1 of the subpixel SP1, the display element DE2 of the subpixel SP2, the display element DE3 of the subpixel SP3, the light-shielding layer 20, and the lens 40 are illustrated, but the other components are not illustrated.

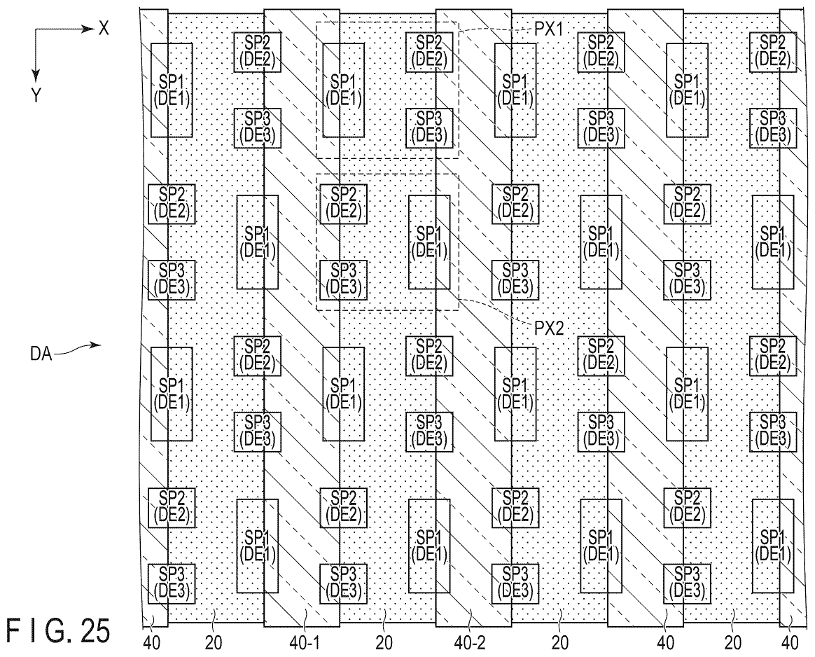

FIG. 25 is a plan view for describing the variation 3.

In the second direction Y of the display area DA, the subpixel SP1, the subpixel SP2, and the subpixel SP3 (or the display element DE1, the display element DE2, and the display element DE3) are arranged in sequence. Further, in the first direction X, the subpixel SP1 and the subpixel SP2 (or the display element DE1 and the display element DE2) are alternately arranged, and the subpixel SP1 and the subpixel SP3 (or the display element DE1 and the display element DE3) are alternately arranged.

The following mainly describes on the two pixels PX1 and PX2 arranged in the second direction Y of the plurality of pixels arranged in the display area DA. The pixel PX1 and the pixel PX2 are located between a lens 40-1 and a lens 40-2 corresponding to two adjacent lenses, among the plurality of lenses 40.

The display element DE1 of the pixel PX1, the display element DE2 of the pixel PX2, and the display element DE3 of the pixel PX2 are arranged in the second direction Y. The display elements DE2 of the pixel PX1, the display element DE3 of the pixel PX1, and the display element DE1 of the pixel PX2 are arranged in the second direction Y.

In the pixel PX1, the light-shielding layer 20 overlaps a part (the right part) of the display element DE1, a part (the left part) of the display element DE2, and a part (the left part) of the display element DE3. The lens 40-1 is located on the left side of the pixel PX1 and overlaps the other part (the left part) of the display element DE1. The lens 40-2 is located on the right side of the pixel PX1 and overlaps the other part (the right part) of the display element DE2 and the other part (the right part) of the display element DE3.

In the pixel PX2, the light-shielding layer 20 overlaps a part (the left part) of the display element DE1, a part (the right part) of the display element DE2, and a part (the right part) of the display element DE3. The lens 40-1 is located on the left side of the pixel PX2 and overlaps the other part (the left part) of the display element DE2 and the other part (the left part) of the display element DE3. The lens 40-2 is located on the right side of the pixel PX2 and overlaps the other part (the right part) of the display element DE1.

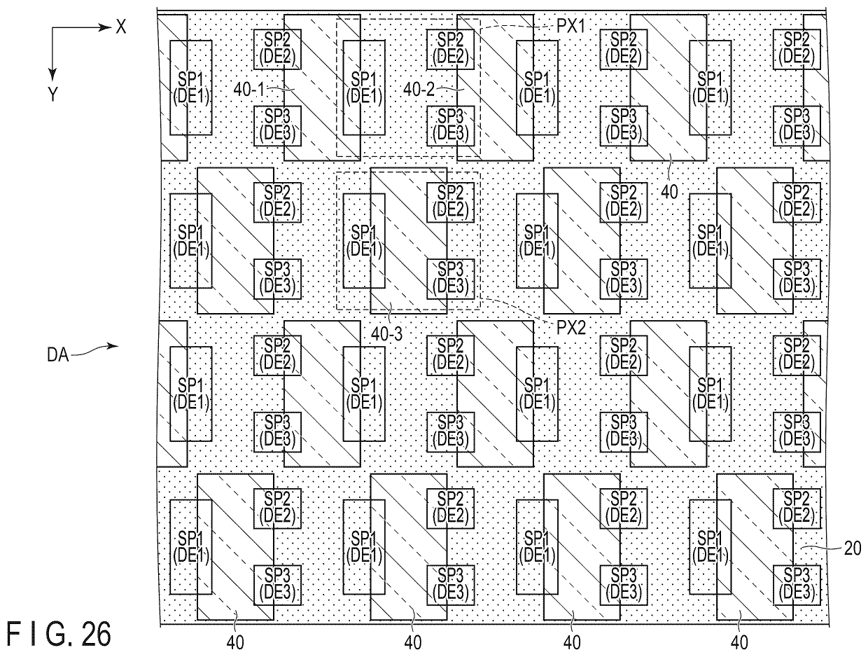

FIG. 26 is a plan view for describing the variation 4.

In the second direction Y of the display area DA, the plurality of subpixels SP1 (or the plurality of display elements DE1) are arranged in the second direction Y, and the subpixel SP2 and the subpixel SP3 (or the display element DE2 and the display element DE3) are alternately arranged. Further, in the first direction X, the subpixel SP1 and the subpixel SP2 (or the display element DE1 and the display element DE2) are alternately arranged, and the subpixel SP1 and the subpixel SP3 (or the display element DE1 and the display element DE3) are alternately arranged.

The following mainly describes on the two pixels PX1 and PX2 arranged in the second direction Y of the plurality of pixels arranged in the display area DA. The pixel PX1 is located between the two adjacent lenses 40-1 and 40-2 among the plurality of lenses 40. The pixel PX2 overlaps a lens 40-3 spaced apart from the lens 40-1 and the lens 40-2.

The display element DE1 of the pixel PX1 and the display element DE1 of the pixel PX2 are arranged in the second direction Y. The display element DE2 of the pixel PX1, the display element DE3 of the pixel PX1, the display element DE2 of the pixel PX2, and the display element DE3 of the pixel PX2 are arranged in the second direction Y.

In the pixel PX1, the light-shielding layer 20 overlaps a part (the right part) of the display element DE1, a part (the left part) of the display element DE2, and a part (the left part) of the display element DE3. The lens 40-1 is located on the left side of the pixel PX1 and overlaps the other part (the left part) of the display element DE1. The lens 40-2 is located on the right side of the pixel PX1 and overlaps the other part (the right part) of the display element DE2 and the other part (the right part) of the display element DE3.

In the pixel PX2, the light-shielding layer 20 overlaps a part (the left part) of the display element DE1, a part (the right part) of the display element DE2, and a part (the right part) of the display element DE3. The lens 40-3 is located substantially at the center of the pixel PX2 and overlaps the other part (the right part) of the display element DE1, the other part (the left part) of the display element DE2, and the other part (the left part) of the display element DE3.

In these variations 3 and 4, a user who observes the display device DSP at the oblique direction to the left side with respect to the normal N can observe the first image as a collection of light beams respectively emitted from the display element DE1 of the pixel PX1 and from the display element DE2 and the display element DE3 of the pixel PX2. Further, a user observing the display device DSP at the oblique direction to the right side with respect to the normal N can observe the second image as a collection of light beams respectively emitted from the display element DE2 and the display element DE3 of the pixel PX1 and from the display element DE1 of the pixel PX2.

These variations 3 and 4 are applicable to any of configuration examples 6 to 10.

In the above embodiment, for example, the display element DE1 corresponds to the first display element. The display element DE2 corresponds to the second display element. The third display element DE3 corresponds to the third display element. The light-shielding layer 20 corresponds to the first light-shielding layer. The light-shielding layer 30 corresponds to the second light-shielding layer. The opening OP1 corresponds to the first opening. The opening OP2 corresponds to the second opening. The opening OP3 corresponds to the third opening. The color filter CF1 corresponds to the first color filter. The color filter CF2 corresponds to the second color filter. The color filter CF3 corresponds to the third color filter.

The embodiments described above can provide a display device capable of improving the display quality.

All of the display devices that can be implemented by a person of ordinary skill in the art through arbitrary design changes to the display device disclosed above as the embodiment come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is

1. A display device comprising:
a substrate;
a first display element and a second display element provided above the substrate;
a rib formed in a lattice shape surrounding each of the first display element and the second display element;
a transparent organic insulating layer provided above the first display element and the second display element; and
a first light-shielding layer provided between the first display element and the second display element on the organic insulating layer, wherein
the first light-shielding layer has a first opening overlapping part of the first display element and a second opening overlapping part of the second display element, and
the first light-shielding layer comprises a first layer located on the organic insulating layer and a second layer located on the first layer and formed of a material different from that of the first layer.

2. The display device of claim 1, wherein
the first layer is a black layer, and
the second layer is a colored layer colored in a first color.

3. The display device of claim 1, wherein
the first light-shielding layer further comprises a third layer located on the second layer,
the first layer is a black layer,
the second layer is a colored layer colored in a first color, and
the third layer is a colored layer colored in a second color different from the first color.

4. The display device of claim 1, wherein
the first light-shielding layer further comprises a third layer located on the second layer,
the first layer is a colored layer colored in a first color,
the second layer is a colored layer colored in a second color different from the first color, and
the third layer is a colored layer colored in a third color different from the first color and the second color.

5. The display device of claim 1, further comprising:
an inorganic insulating layer provided above the first display element and the second display element; and
a second light-shielding layer formed in a lattice shape overlapping the rib, provided on the inorganic insulating layer, and covered with the organic insulating layer,
each of the first opening and the second opening overlaps part of the second light-shielding layer, and
the second light-shielding layer comprises a fourth layer located on the inorganic insulating layer and a fifth layer located on the fourth layer and formed of a material different from that of the fourth layer.

6. The display device of claim 5, wherein
the fourth layer is formed of the same material as that of the first layer, and
the fifth layer is formed of the same material as that of the second layer.

7. The display device of claim 5, wherein
the fourth layer is a black layer, and
the fifth layer is a colored layer colored in a first color.

8. The display device of claim 5, wherein
the second light-shielding layer further comprises a sixth layer located on the fifth layer,
the fourth layer is a black layer,
the fifth layer is a colored layer colored in a first color, and
the sixth layer is a colored layer colored in a second color different from the first color.

9. The display device of claim 5, wherein
the second light-shielding layer further comprises a sixth layer located on the fifth layer,
the fourth layer is a colored layer colored in a first color,
the fifth layer is a colored layer colored in a second color different from the first color, and
the sixth layer is a colored layer colored in a third color different from the first color and the second color.

10. The display device of claim 1, further comprising:
an inorganic insulating layer provided above the first display element and the second display element;
a first color filter provided on the inorganic insulating layer, overlapping the first display element, covered with the organic insulating layer, and colored in a first color; and
a second color filter provided on the inorganic insulating layer, overlapping the second display element, covered with the organic insulating layer, and colored in a second color different from the first color, wherein
each of the first opening and the second opening overlaps part of the first color filter and part of the second color filter.

11. The display device of claim 10, wherein
the first display element is configured to display the first color, and
the second display element is configured to display the second color.

12. The display device of claim 10, further comprising:
a second light-shielding layer formed in a lattice shape overlapping the rib and provided on the inorganic insulating layer between the first color filter and the second color filter.

13. The display device of claim 10, further comprising:
a third color filter provided on the inorganic insulating layer, covered with the organic insulating layer, and colored in a third color different from the first color and the second color, wherein
the first color filter, the second color filter, and the third color filter are stacked in an area overlapping the rib.

14. The display device of claim 1, further comprising:
a lens overlapping each of the first opening and the second opening on the organic insulating layer, wherein
an edge of the lens overlaps the first light-shielding layer.

15. The display device of claim 14, further comprising:
a low-refractive-index layer provided on the first light-shielding layer, covering the edge, exposing an apex portion of the lens, and having a refractive index lower than that of the lens.

16. The display device of claim 14, further comprising:
an inorganic insulating layer provided above the first display element and the second display element; and
a second light-shielding layer formed in a lattice shape overlapping the rib, provided on the inorganic insulating layer, and covered with the organic insulating layer, wherein
the lens overlaps part of the second light-shielding layer.

17. The display device of claim 14, further comprising:
an inorganic insulating layer provided above the first display element and the second display element;
a first color filter provided on the inorganic insulating layer, overlapping the first display element, covered with the organic insulating layer, and colored in a first color; and
a second color filter provided on the inorganic insulating layer, overlapping the second display element, covered with the organic insulating layer, and colored in a second color different from the first color, wherein
the lens overlaps part of the first color filter and part of the second color filter.

18. The display device of claim 1, wherein
each of the first display element and the second display element comprises:
a lower electrode;
an upper electrode; and
an organic layer provided between the lower electrode and the upper electrode and including a light emitting layer, and
the light emitting layer included in the first display element is formed of a material different from that of the light emitting layer included in the second display element.

19. The display device of claim 1, further comprising:
a sealing layer formed of an inorganic insulating material and covering the first display element and the second display element;
a resin layer provided on the sealing layer; and
an inorganic insulating layer provided between the resin layer and the organic insulating layer, wherein
a thickness of the organic insulating layer is greater than that of the resin layer.

20. The display device of claim 1, wherein
each of a plurality of pixels comprises the first display element and the second display element arranged in a first direction,
a first pixel and a second pixel included in the plurality of pixels are arranged in a second direction intersecting the first direction,
the first display element of the first pixel and the second display element of the second pixel are arranged in the second direction, and
the second display element of the first pixel and the first display element of the second pixel are arranged in the second direction.
